(19) United States
(12) Patent Application Publication
(10) Pub. No.: US 2015/0303115 A1
(43) Pub. Date: Oct. 22, 2015

(54) MODIFICATION OF A THRESHOLD VOLTAGE OF A TRANSISTOR BY OXYGEN TREATMENT

(71) Applicant: GLOBALFOUNDRIES INC., Grand Cayman (KY)

(72) Inventors: Yiqun LIU, Clifton Park, NY (US); Jeasung PARK, Ballston SPA, NY (US); Chandra REDDY, Ballston Lake, NY (US)

(73) Assignee: GLOBALFOUNDRIES INC., Grand Cayman (KY)

(21) Appl. No.: 14/257,899

(22) Filed: Apr. 21, 2014

(51) Int. Cl. H01L 21/8234; H01L 21/02; H01L 21/28; H01L 27/088

(52) U.S. Cl. CPC H01L 21/82345; H01L 27/088; H01L 21/02694; H01L 21/28088

(57) ABSTRACT

Methodologies and resulting devices are provided for modified FET threshold voltages. Embodiments include: providing an active region of a transistor on a semiconductor substrate; depositing a workfunction metal on the active region; and modifying a threshold voltage of the transistor by treating the workfunction metal with oxygen. Other embodiments include: providing first and second active regions in a semiconductor substrate for first and second transistors, respectively; forming a first workfunction metal on the first active region; forming a second workfunction metal on the second active region; and modifying a first threshold voltage level of the first transistor, a second threshold voltage level of the second transistor, or a combination thereof by treating the first workfunction metal, second workfunction metal, or a combination thereof with oxygen, wherein the second threshold voltage level is greater than the first threshold voltage level.

### TECHNICAL FIELD

The present disclosure relates to a manufacture of semiconductor devices, such as integrated circuits (ICs). The present disclosure is particularly applicable to tuning a threshold voltage level of a transistor, particularly a p-type field effect transistor (PFET), for 20 nanometer (nm) nodes and beyond.

### BACKGROUND

In a fabrication of semiconductor devices, IC designs and resulting devices may need to support PFETs having multiple threshold voltages. Some methods to support multiple threshold voltages of PFETs rely upon different cap titanium nitride (TiN) thicknesses under TiN workfunction metal of the PFETs. However, the resulting modulation is insufficient for multi-threshold voltage requirements. Further, such different TiN thicknesses may negatively affect fin geometry of resulting devices, particularly when the multiple threshold voltages differ by more than 100 millivolts (mV), which in turn impacts a manufacturability of resulting devices.

A need therefore exists for methodology and resulting devices allowing for a modification of a threshold voltage level of PFETs without affecting fin geometry of resulting devices, particularly when threshold voltage levels of PFETs differ by more than 100 mV.

### SUMMARY

An aspect of the present disclosure is a method of modifying, in situ, a threshold voltage level of a transistor by treating (e.g., doping to a depth of at least ¼ of a total thickness) the workfunction metal with oxygen.

Another aspect of the present disclosure is a method of forming transistors having different threshold voltage levels that includes, inter alia, modifying a threshold voltage level of at least one of the transistors by treating the workfunction metal with oxygen.

An additional aspect of the present disclosure is a device having, inter alia, a first transistor having a workfunction metal portion being doped with oxygen and a second transistor having a threshold voltage level greater than a threshold voltage level of the first transistor.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing an active region of a transistor on a semiconductor substrate; depositing a workfunction metal on the active region; and modifying a threshold voltage of the transistor by treating the workfunction metal with oxygen.

Aspects include treating the workfunction metal with oxygen by implanting oxygen to a depth of at least ¼ of a thickness of the workfunction metal. Additional aspects include heating the substrate to a temperature exceeding 350 degrees Celsius (° C.) during the treating, the temperature being based on the threshold voltage. Some aspects include heating the substrate to a temperature exceeding 440° C. during the treating, the temperature being based on the threshold voltage. Further aspects include the treating of the workfunction metal being of a first portion of the workfunction metal, the method further including: treating a second portion of the workfunction metal with oxygen by implanting oxygen to a depth of at least ¼ of a thickness of the workfunction metal, wherein the second portion forms an upper surface of the workfunction metal. Additional aspects include a thickness of the treated workfunction metal being ¼ to ½ of a thickness of the workfunction metal. Some aspects include the workfunction metal being titanium nitride (TiN) and the transistor being a PFET. Further aspects include an electron voltage level of the transistor being between 4.8 electron volts and 5.1 electron volts.

Another aspect of the present disclosure is a method including: providing first and second active regions in a semiconductor substrate for first and second transistors, respectively; forming a first workfunction metal on the first active region; forming a second workfunction metal on the second active region; and modifying a first threshold voltage level of the first transistor, a second threshold voltage level of second transistor, or a combination thereof by treating the first workfunction metal, second workfunction metal, or a combination thereof with oxygen, wherein the second threshold voltage level is greater than the first threshold voltage level.

Some aspects include the second threshold voltage level being greater than the first threshold voltage level by at least 100 millivolts (mV) and the first and second workfunction metals having a difference of thickness of no more than 20 angstroms (Å). Additional aspects include forming the first and second workfunction metals by: depositing a first workfunction material on the first active region; and depositing a second workfunction material on the first and second active regions. Further aspects include treating the first workfunction material with oxygen, prior to depositing the second workfunction material. Some aspects include the depositing of the first workfunction material including: depositing an etch stop layer on the first and second active regions; depositing the first workfunction material on the etch stop layer; treating the first workfunction material with oxygen; and removing, after the treating of the first workfunction material, a portion of the first workfunction material on the second active region to expose an upper surface of the etch stop layer on the second active region. Additional aspects include the depositing of the second workfunction material further including: depositing the second workfunction material directly on the first workfunction material in the first active region and directly on an exposed portion of the etch stop layer over the second active region. Further aspects include: providing a third active region in the semiconductor substrate; depositing the etch stop layer on the third active region; depositing the first workfunction material or the first and second workfunction materials on the etch stop layer on the third active region; and removing the first workfunction material or the first and second workfunction material from the third active region to expose an upper surface of the etch stop layer on the third active region. Some aspects include: providing a dielectric layer directly on the first and second active regions, the dielectric layer including an interlayer dielectric and a high-k dielectric; and providing a TiN layer directly on the dielectric layer, wherein the etch stop layer is formed on the TiN layer.

Another aspect of the present disclosure is a device including: a first transistor having a first threshold voltage level and positioned on a first active region of a semiconductor substrate, the first transistor including a first workfunction metal including first and second portions of TiN, the second portion being doped with oxygen; and a second transistor having a second threshold voltage level and positioned on a second active region of the semiconductor substrate, the second transistor including a second workfunction metal including TiN, wherein the second threshold voltage level is greater than the first threshold voltage level.

Some aspects include the first workfunction metal further including a third portion of TiN, the third portion being doped with oxygen, and the second or third portion being an upper surface of the first workfunction metal. Additional aspects include the second threshold voltage level being greater than the first threshold voltage level by at least 100 mV, and the first and second workfunction metals having a difference of thickness of no more than 20 A. Further aspects include the second workfunction metal including first and second portions of TiN, the second portion of the second workfunction metal being doped with oxygen, a thickness of the second portion of the first workfunction metal being ¼ to ½ of a thickness of the first workfunction metal, and a thickness of the second portion of the second workfunction metal being ¼ to ½ of a thickness of the second workfunction metal.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A and 1B illustrate first and second transistors utilizing in-situ oxygen treatment, respectively, in accordance with exemplary embodiments;

FIG. 2 illustrates effects of in-situ oxygen treatment to tune a threshold voltage level of a transistor, in accordance with exemplary embodiments;

FIG. 3 is a flow diagram of a process for modifying a threshold voltage level of a transistor by an oxygen treatment, in accordance with an exemplary embodiment;

FIGS. 4 through 7 illustrate a process for modifying a threshold voltage level of a transistor by an oxygen treatment, in accordance with an exemplary embodiment; and

FIGS. 8 through 13 illustrate exemplary results of modifying a threshold voltage level of a transistor by an oxygen treatment, according to an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems of insufficient modulation and irregular in geometry attendant upon employing different workfunction metal thicknesses of the PFETs to obtain multiple threshold voltages. The problems are solved, for instance, by treating the workfunction metals with oxygen.

Methodology in accordance with embodiments of the present disclosure includes: providing an active region of a transistor on a semiconductor substrate; depositing a workfunction metal on the active region; and modifying a threshold voltage of the transistor by treating the workfunction metal with oxygen.

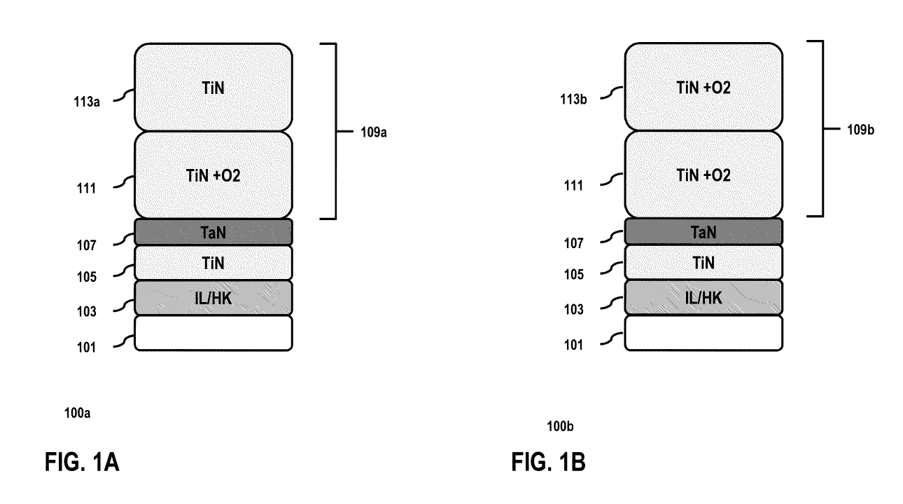

FIGS. 1A and 1B illustrate transistors 100a and 100b, respectively, having threshold voltages tuned by an oxygen treatment. Transistors 100a and 100b include active region 101, an inter-layer dielectric and a high-k (e.g., having a relative dielectric constant greater than 3.9) layer 103, capTiN layer 105, etch stop layer (e.g., tantalum nitride (TaN)) 107. The cap TiN layer 105 may have a thickness of 10 Å to 15 Å, e.g. 12 Å, and the etch stop layer 107 may have a thickness of 10 Å to 20 Å, e.g. 10 Å. As shown in FIG. 1A, workfunction metal 109a has a first workfunction material (e.g., TiN) 111 doped with oxygen and a second workfunction material (e.g., TiN) 113a. Similarly, FIG. 1B illustrates workfunction metal 109b having a first workfunction material (e.g., TiN) 111 doped with oxygen, but with a second workfunction material (e.g., TiN) 113b being doped with oxygen. The doping may result in an implanting of oxygen to a depth of, for instance, at least ¼th, for example between ¼th to ½, of a thickness of a workfunction metal (e.g., 109a, 109b, etc.).

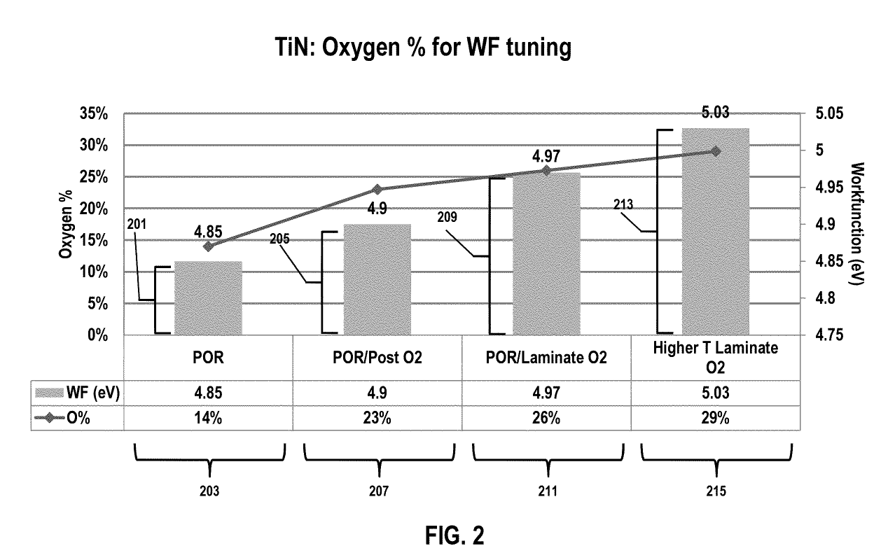

FIG. 2 illustrates workfunction electron levels resulting from different oxygen percentages and different methods of introducing the oxygen. As shown, an electron voltage 201 is indicated for workfunction metal 203 with 14% oxygen, and an electron voltage 205 is indicated for workfunction metal 207 with 23% oxygen, introduced after TiN deposition. FIG. 2 further illustrates electron voltages 209 and 213 for workfunction metals 211 and 215, which have 26% and 29% oxygen levels, respectively. For workfunction metals 211 and 215, the oxygen is introduced during TiN deposition using a temperature exceeding 380° C. and 440° C., respectively. A transistor may be modified by treating with oxygen, as further described below, to an electron voltage level of, for instance, between 4.8 electron volts and 5.1 electron volts. As shown, the electron voltages 201, 205, 209, and 213 are modified from 4.85 eV to 5.03 eV. Moreover, the electron voltages have corresponding impacts on a threshold voltage of transistors having the workfunction metals 203, 207, 211, and 215. Accordingly, a selection of oxygen treatments for workfunction metals and the modification of temperatures during the oxygen treatment of the workfunction metals may be used for tuning of a threshold voltage level in resulting transistors.

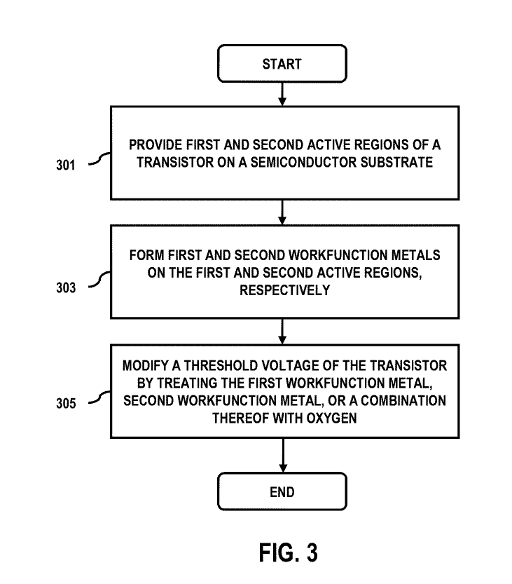

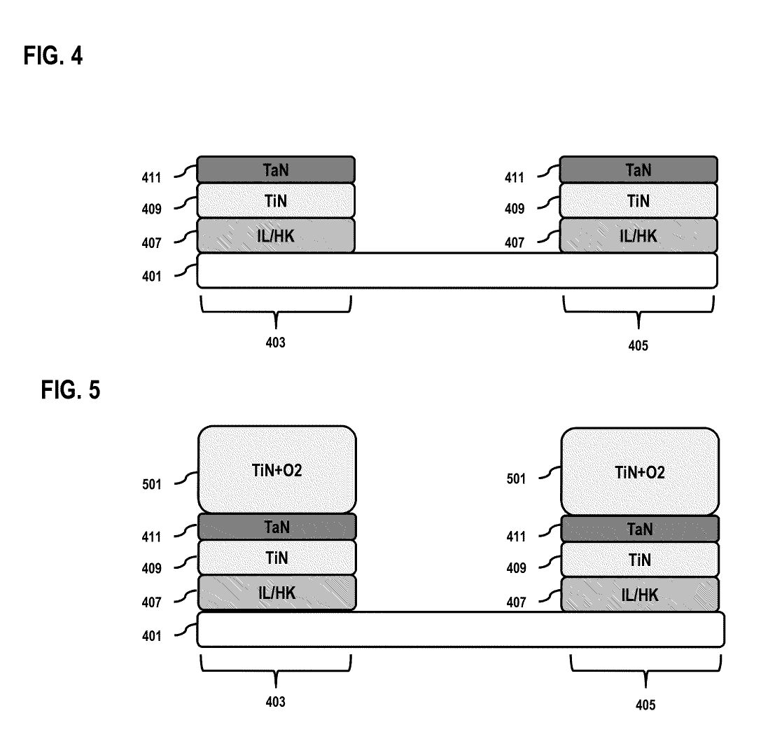

FIG. 3 illustrates a flow diagram for modifying a threshold voltage of a transistor by treating a workfunction metal with oxygen. The steps of FIG. 3 are discussed with respect to FIGS. 4 through 7. In step 301, first and second active regions of a transistor are provided on a semiconductor substrate. As illustrated in FIG. 4, a substrate 401 is provided having active regions 403 and 405. A dielectric layer 407, a cap TiN layer 409, and an etch stop layer 411 formed of TaN are sequentially formed on the active regions. Thicknesses of layers 409 and 411 are similar to the thicknesses of 105 and 107, respectively, in FIGS. 1A and 1B.

Next, in step 303, first and second workfunction metals are formed on the first and second active regions, respectively. Adverting to FIG. 5, a workfunction material 501 is deposited on the first and second active regions 403 and 405 to a thickness of 15 Å to 25 Å, for example 20 Å. Then, the workfunction material 501 is treated, as in step 305, with oxygen.

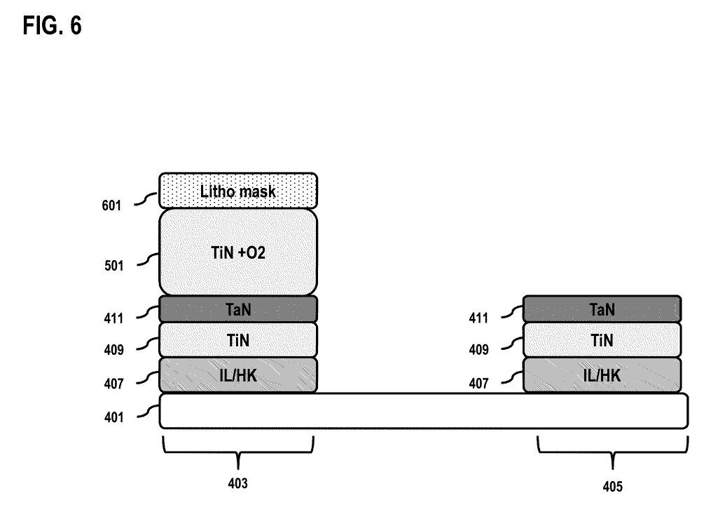

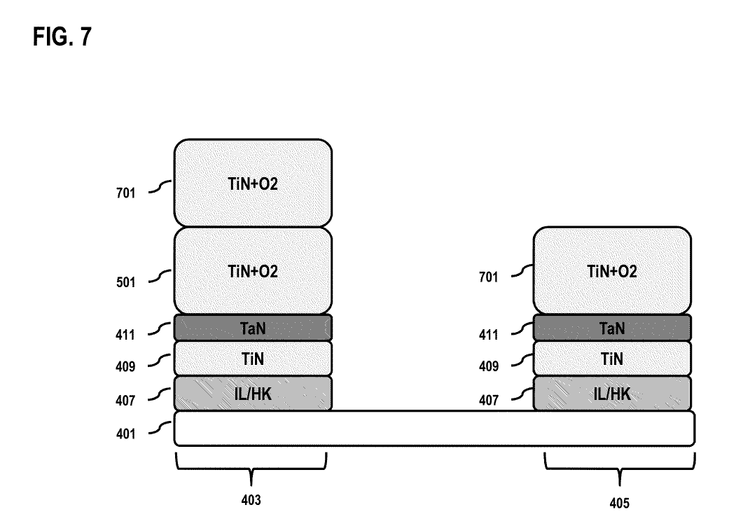

A transistor having active region 403 and a transistor having active region 405 may be modified to have different threshold voltages by the steps illustrated in FIGS. 6 and 7. Adverting to FIG. 6, a lithography mask 601 is applied over the active region 403, and the portion of the workfunction material 501 over the active region 405 is removed using the etch stop layer 411 as an etch stop. Next, as illustrated in FIG. 7, a workfunction material 701, e.g. TiN, is deposited on the first and second active regions 403 and 405 to a thickness of 15 Å to 25 Å, for example 20 Å, and treated with oxygen to further modify a difference in threshold voltages. As shown, a transistor having active region 403 and a transistor having active region 405 may have a difference of threshold voltages exceeding 100 mV with a difference in workfunction metal thickness of no more than 20 Å.

Furthermore, a third active region (not shown) may be formed similar to active region 403 (e.g., with workfunction materials 501 and 701) or as active region 405 (e.g., with workfunction material 701) and the etch stop layer 411 may be used as an etch stop to remove workfunction material 501 and 701 or workfunction material 701. Accordingly, a resulting workfunction metal may be further modified to exclude workfunction materials 501 and 701 to allow for larger differences in threshold voltages for transistors.

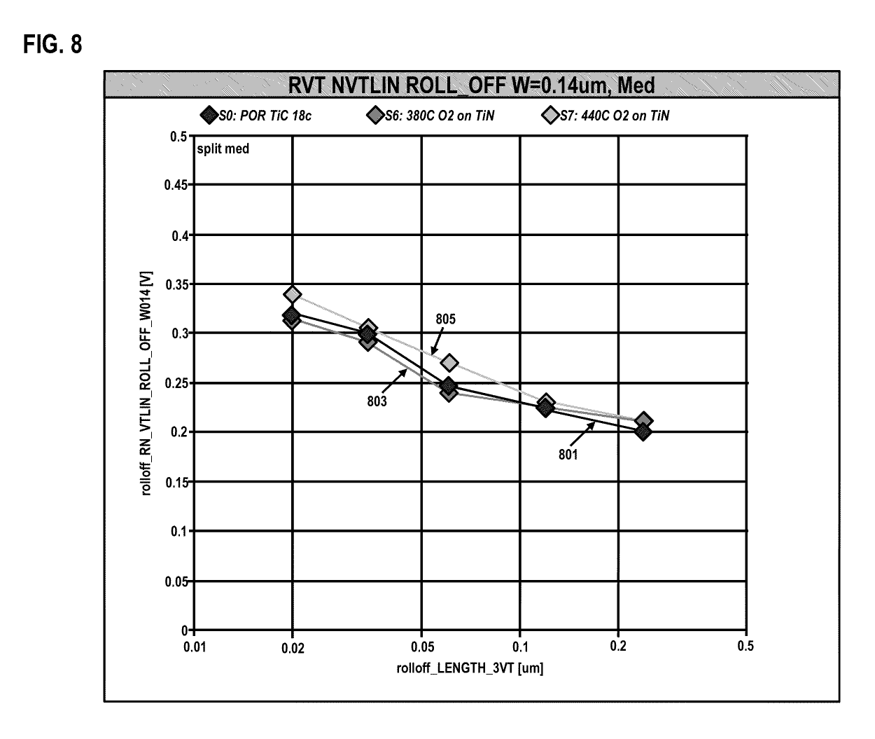

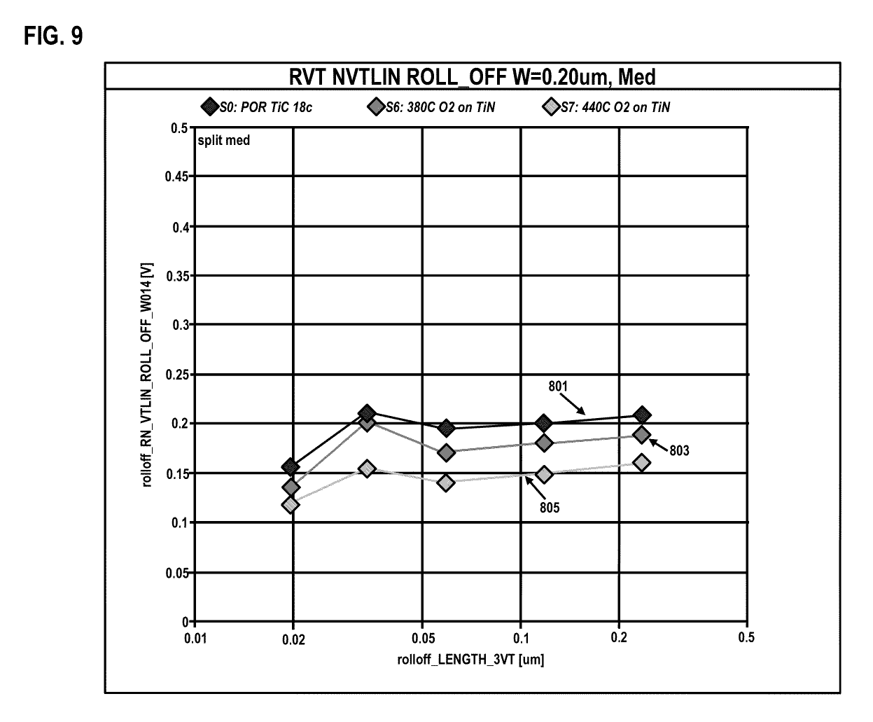

FIG. 8 illustrates a graph for an n-type FET (NFET) having a threshold voltage in volts (V) on the y-axis and a rolloff length in microns (μm) on the x-axis for a process 801 using an in situ oxygen doping of the workfunction metal, a process 803 using an in situ oxygen doping during deposition of the workfunction metal at temperatures exceeding 380° C., and a process 805 using an in situ oxygen doping during deposition of the workfunction metal at temperatures exceeding 440° C. Similarly, FIG. 9 illustrates a graph for a PFET having a threshold voltage in volts on the y-axis and a rolloff length in microns on the x-axis for processes 801, 803, and 805. As shown, the different processes result in relatively similar threshold voltages for the NFET but different threshold voltages for the PFET. As such, the processes 801, 803, and 805 for modifying threshold voltages for PFETs of an IC design do not significantly impact NFETs of the IC design while allowing for the different threshold voltages for the PFETs.

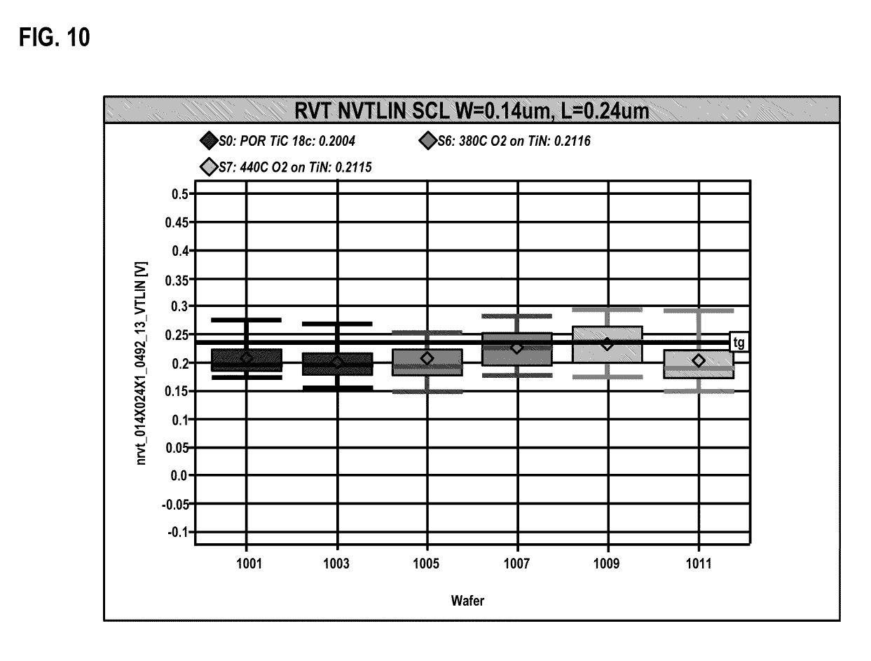

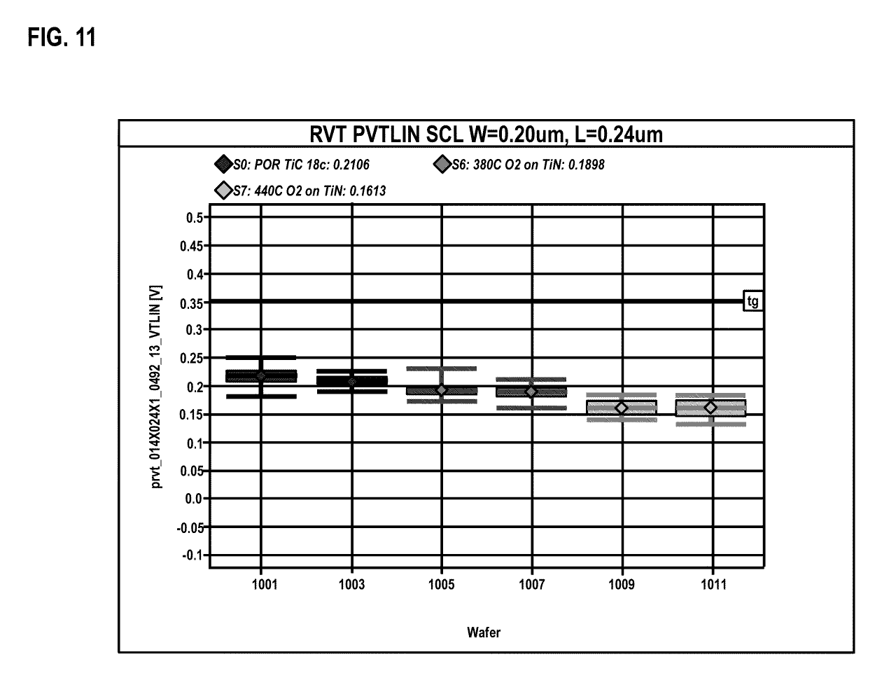

FIG. 10 illustrates a graph for an NFET having a threshold voltage range in volts for a wafers 1001 and 1003 utilizing a process of in situ oxygen doping, wafers 1005 and 1007 utilizing a process of in situ oxygen doping during deposition of the workfunction metal at temperatures exceeding 380° C., and wafers 1009 and 1011 utilizing a process of in situ oxygen doping f during deposition of the workfunction metal at temperatures exceeding 440° C. Similarly, FIG. 11 illustrates a graph for a PFET having a threshold voltage range in volts for the PFETs of the wafers 1001 through 1011. Like FIGS. 8 and 9, the different processes result in relatively similar threshold voltage ranges for the NFET but different threshold voltage ranges for the PFET. As such, the processes for modifying threshold voltages for PFETs of an IC design do not significantly impact NFETs of the IC design while allowing for the different threshold voltages for the PFETs.

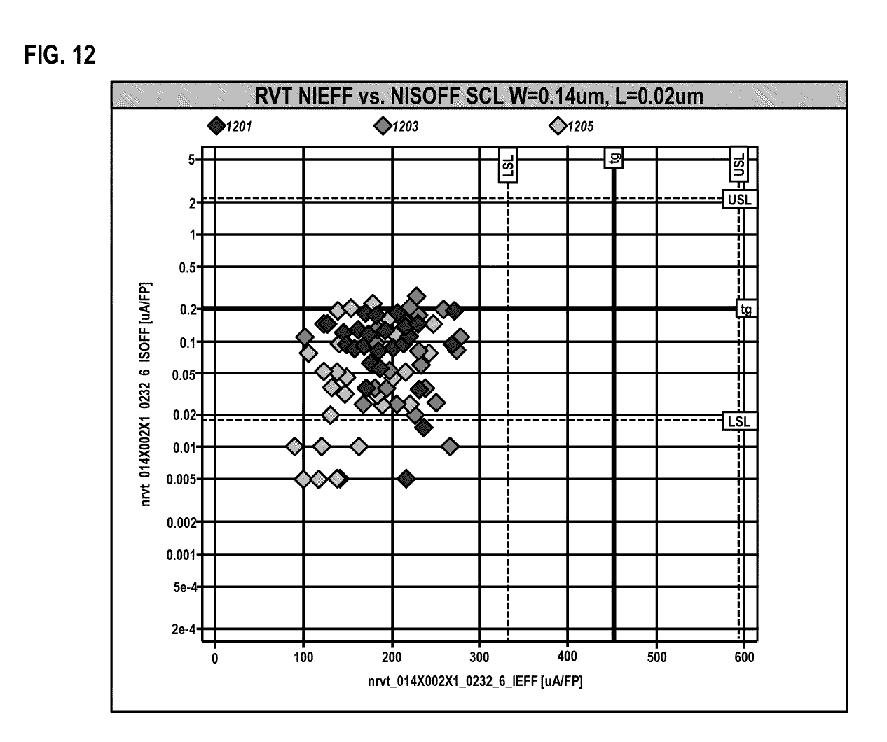

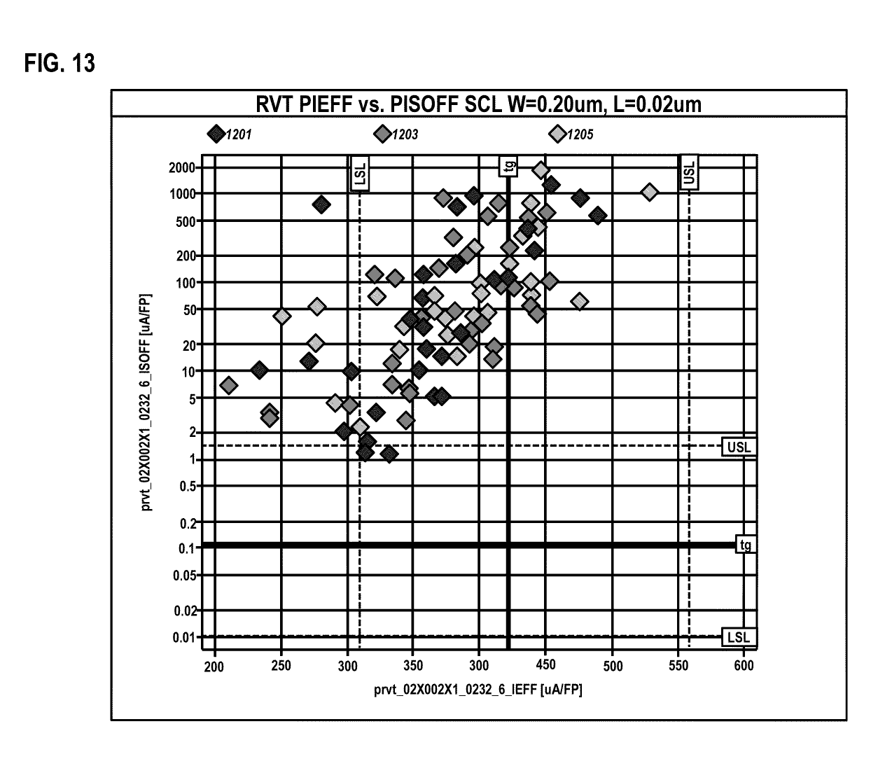

FIG. 12 illustrates a graph for an NFET having a threshold voltage in volts on the y-axis and a current in micro-amps (μA) on the x-axis for a process 1201 using an in situ oxygen doping, a process 1203 using an in situ oxygen doping during deposition of the workfunction metal at temperatures exceeding 380° C., and a process 1205 using an in situ oxygen doping during deposition of the workfunction metal at temperatures exceeding 440° C. Similarly, FIG. 13 illustrates a graph for a PFET having a threshold voltage in volts on the y-axis and a current in micro-amps on the x-axis for processes 1201, 1203, and 1205. As shown, the different processes result in relatively similar threshold voltages for the NFET but different threshold voltages for the PFET. As such, the processes 1201, 1203, and 1205 for modifying threshold voltages for PFETs of an IC design do not significantly impact NFETs of the IC design while allowing for the different threshold voltages for the PFETs.

The embodiments of the present disclosure achieve several technical effects, including a modification of a threshold voltage of a PFET transistor without significantly affecting a geometry of a fin of the PFET transistor or electrical performance of NFETs. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices, particularly for 20 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing an active region of a transistor on a semiconductor substrate;
depositing a workfunction metal on the active region; and
modifying a threshold voltage of the transistor by treating the workfunction metal with oxygen.

2. The method according to claim 1, comprising:
treating the workfunction metal with oxygen by implanting oxygen to a depth of at least ¼ of a thickness of the workfunction metal.

3. The method according to claim 1, comprising:
heating the substrate to a temperature exceeding 350 degrees Celsius (° C.) during the treating, the temperature being based on the threshold voltage.

4. The method according to claim 1, comprising:
heating the substrate to a temperature exceeding 440 degrees Celsius (° C.) during the treating, the temperature being based on the threshold voltage.

5. The method according to claim 1, wherein the treating of the workfunction metal with oxygen is of a first portion of the workfunction metal, the method further comprising:
treating a second portion of the workfunction metal with oxygen by implanting oxygen to a depth of at least ¼ of a thickness of the workfunction metal, wherein the second portion forms an upper surface of the workfunction metal.

6. The method according to claim 1, wherein a thickness of the treated workfunction metal is ¼ to ½ of a thickness of the workfunction metal.

7. The method according to claim 1, wherein the workfunction metal is titanium nitride (TiN) and the transistor is a p-type field-effect transistor.

8. The method according to claim 1, wherein an electron voltage level of the transistor is between 4.8 electron volts and 5.1 electron volts.

9. A method comprising:
providing first and second active regions in a semiconductor substrate for first and second transistors, respectively;
forming a first workfunction metal on the first active region;
forming a second workfunction metal on the second active region; and
modifying a first threshold voltage level of the first transistor, a second threshold voltage level of second transistor, or a combination thereof by treating the first workfunction metal, second workfunction metal, or a combination thereof with oxygen, wherein the second threshold voltage level is greater than the first threshold voltage level.

10. The method according to claim 9, wherein the second threshold voltage level is greater than the first threshold voltage level by at least 100 millivolts (mV) and the first and second workfunction metals have a difference of thickness of no more than 20 angstroms (Å).

11. The method according to claim 9, comprising forming the first and second workfunction metals by:
depositing a first workfunction material on the first active region; and
depositing a second workfunction material on the first and second active regions.

12. The method according to claim 11, further comprising;
treating the first workfunction material with oxygen, prior to depositing the second workfunction material.

13. The method according to claim 11, wherein the depositing of the first workfunction material comprises:
depositing an etch stop layer on the first and second active regions;
depositing the first workfunction material on the etch stop layer;
treating the first workfunction material with oxygen; and
removing, after the treating of the first workfunction material, a portion of the first workfunction material on the second active region to expose an upper surface of the etch stop layer on the second active region.

14. The method according to claim 13, wherein the depositing of the second workfunction material further comprises:
depositing the second workfunction material directly on the first workfunction material in the first active region and directly on an exposed portion of the etch stop layer over the second active region.

15. The method according to claim 13, further comprising:
providing a third active region in the semiconductor substrate;
depositing the etch stop layer on the third active region;
depositing the first workfunction material or the first and second workfunction materials on the etch stop layer on the third active region; and
removing the first workfunction material or the first and second workfunction material from the third active region to expose an upper surface of the etch stop layer on the third active region.

16. The method according to claim 13, comprising:
providing a dielectric layer directly on the first and second active regions, the dielectric layer comprising an interlayer dielectric and a high-k dielectric; and
providing a titanium nitride (TiN) layer directly on the dielectric layer, wherein the etch stop layer is formed on the TiN layer.

17. An apparatus comprising:
a first transistor having a first threshold voltage level and positioned on a first active region of a semiconductor substrate, the first transistor including a first workfunction metal comprising first and second portions of titanium nitride (TiN), the second portion being doped with oxygen; and
a second transistor having a second threshold voltage level and positioned on a second active region of the semiconductor substrate, the second transistor including a second workfunction metal comprising titanium nitride (TiN), wherein the second threshold voltage level is greater than the first threshold voltage level.

18. The apparatus according to claim 17, wherein the first workfunction metal further comprises a third portion of TiN, the third portion being doped with oxygen, and the second or third portion being an upper surface of the first workfunction metal.

19. The apparatus according to claim 17, wherein the second threshold voltage level is greater than the first threshold voltage level by at least 100 millivolts (mV), and the first and second workfunction metals have a difference of thickness of no more than 20 angstroms (Å).

20. The apparatus according to claim 17, wherein the second workfunction metal comprises first and second portions of titanium nitride (TiN), the second portion of the second workfunction metal being doped with oxygen, a thickness of the second portion of the first workfunction metal being ¼ to ½ of a thickness of the first workfunction metal, and a thickness of the second portion of the second workfunction metal being ¼ to ½ of a thickness of the second workfunction metal.
